(19) United States
(12) Patent Application Publication
(10) Pub. No.: US 2018/0247238 A1
(43) Pub. Date: Aug. 30, 2018

(54) WORK RANGE VISUALIZATION DEVICE AND WORK RANGE VISUALIZATION METHOD

(71) Applicants: Kabushiki Kaisha Toshiba, Minato-ku (JP); Toshiba Energy Systems and Solutions Corporation, Kawasaki-shi (JP)

(72) Inventors: Hidetatsu Hiraki, Kawasaki (JP); Makoto Hatakeyama, Yokosuka (JP); Toyohiro Umeki, Yokohama (JP)

(73) Assignees: Kabushiki Kaisha Toshiba, Minato-ku (JP); Toshiba Energy Systems and Solutions Corporation, Kawasaki-shi (JP)

(21) Appl. No.: 15/904,547

(22) Filed: Feb. 26, 2018

(30) Foreign Application Priority Data
Feb. 27, 2017 (JP) 2017-035462

(51) Int. Cl. G06Q 10/06; G06T 11/20; G06T 11/00

(52) U.S. Cl. CPC G06Q 10/0633; G06F 17/50; G06T 11/001; G06T 11/206

(57) ABSTRACT

A work range visualization device in an embodiment includes a design data storage, an operation process data storage, a display condition data storage, and a drawing processor. The design data storage stores design data on work objects. The operation process data storage stores operation process data based on the design data. The display condition data storage stores a designated period including present and future. The drawing processor extracts data for a first, a second, and a third work object from the design data and the operation process data according to the designated period, and creates a drawing in which each of the first, the second and the third work object is distinguishable. The first work object is an object completed before the designated period. The second work object is an object planned to be operated within the designated period. The third work object is an object planned to be operated after the designated period.

### CROSS-REFERENCE TO RELATED APPLICATION

This application is based upon and claims the benefit of priority from Japanese Patent Application No. 2017-035462, filed on Feb. 27, 2017; the entire contents of which are incorporated herein by reference.

### FIELD

Embodiments described herein generally relate to a work range visualization device and a work range visualization method.

### BACKGROUND

In a large project such as construction of a power station, works by many companies are carried out in parallel. Therefore, it is important to proceed arrangement of the works and safe measures after adjusting the work ranges of the companies and grasping the states of the works by the other companies in a process meeting.

For the work adjustment in the process meeting, conventionally, work areas of the companies are illustrated and work contents are described in words in a construction area chart.

In recent years, shortening of the construction period is required, and there occurs a need to perform construction works in parallel in the same work area depending on the work contents. Therefore, the work adjustment using only the work area chart may have a difficulty in sufficiently carrying out construction works in parallel.

For this reason, it is necessary to adjust the works after confirming the progress status using a plan view and a cubic diagram illustrating work objects in addition to the construction area.

However, it is not always easy to confirm the work range in a certain period such as this week or the next week.

### BRIEF DESCRIPTION OF THE DRAWINGS

FIG. 1 is a block diagram illustrating an example of a work plan range visualization apparatus.

FIG. 2 is a chart illustrating an example of a construction process chart.

FIG. 3 is a chart illustrating an example of a display condition setting screen.

FIG. 4 is a flowchart illustrating the operation of the work plan range visualization apparatus.

FIG. 5 is a schematic view illustrating an example of the drawing created by the work plan range visualization apparatus.

### DETAILED DESCRIPTION

Hereinafter, an embodiment of the present invention will be described in detail referring to the drawings.

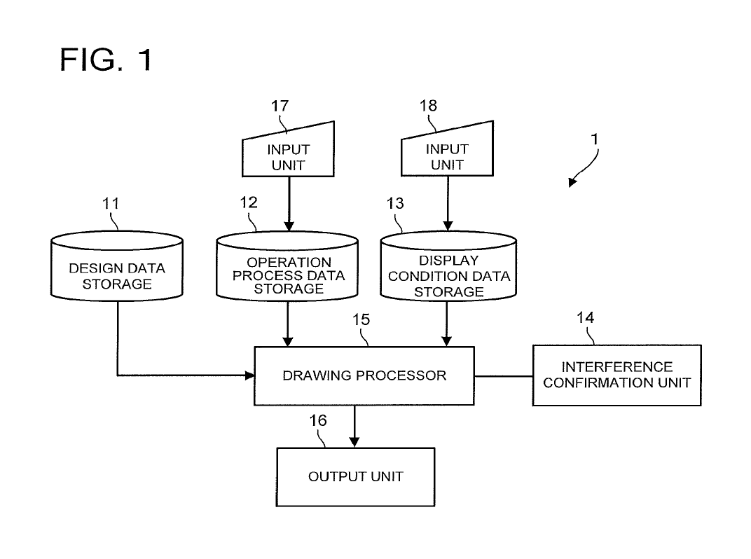

FIG. 1 is a block diagram illustrating a work plan range visualization apparatus 1 according to one embodiment. In the work plan range visualization apparatus 1, a drawing of a work object whose work plan can be grasped over time is displayed in the same window or on the same paper sheet. The work plan range visualization apparatus 1 is usable, for example, for process management of construction of a power generation plant such as a power station.

The work plan range visualization apparatus 1 includes a design data storage 11, an operation process data storage 12, a display condition data storage 13, an interference confirmation unit 14, a drawing processor 15, and an output unit 16.

The design data storage 11 stores design data on work objects. The operation process data storage 12 stores operation process data based on the design data. The display condition data storage 13 sets a display method of the drawing. The interference confirmation unit 14 confirms interference between work objects (including period, device, or member) in the drawing created by the drawing processor 15, based on predetermined interference conditions between the work objects. The drawing processor 15 creates the drawing of the work objects. The output unit 16 displays the drawing of the work objects on a screen or prints the drawing of the work objects.

The design data storage 11, the operation process data storage 12, and the display condition data storage 13 can be composed of a storage device (for example, memory, or hard disk drive) that stores data.

The interference confirmation unit 14 has a storage part (for example, memory, or hard disk drive) and a determination part. The determination part can be composed of software (program) and hardware (processor) operating according to the software. The processor is an arithmetic unit (for example, Central Processing Unit: CPU) that performs an arithmetic operation on data. However, the determination part may be composed only of hardware without using software.

The drawing processor 15 can be composed of software and hardware (processor) operating according to the software, as with the determination part of the interference confirmation unit 14. However, the drawing processor 15 may be composed only of hardware without using software.

The design data storage 11 stores design data on work objects. The design data is data on the position, shape, dimension (length, width, height and the like), weight and the like of a building and a facility such as piping being the work object, and is stored in the form of numerical information, planar drawing data, three-dimensional Computer Aided Design data (hereinafter, referred to as “3D CAD data”) and the like.

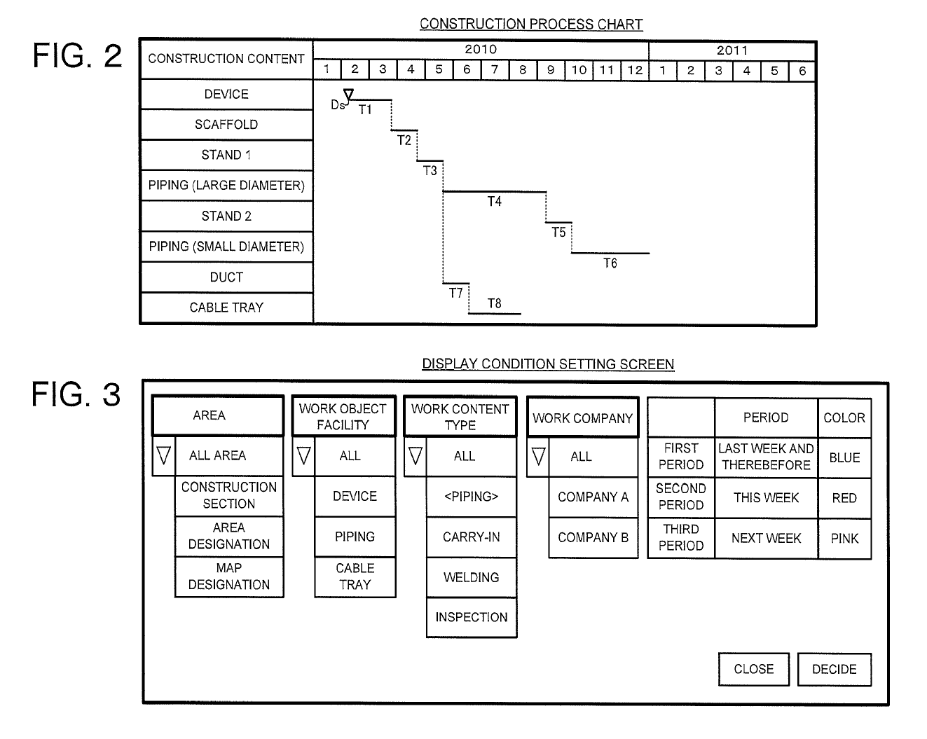

The operation process data storage 12 stores operation process data based on the design data. The operation process data means a work sequence and a work schedule of each of the work objects in the design data, and is displayed, for example, as a construction process chart as in FIG. 2. The operation process data storage 12 may store contents of work for each of the work objects, a construction contractor executing each work, and a work sequence and a work schedule (work process chart) of each area in the case where a construction object area is partitioned into a plurality of sections.

The operation process data stored in the operation process data storage 12 can be updated as needed according to the progress of an actual work and changed contents. The operation process data can be updated using an input unit 17 connected to the operation process data storage 12. The input unit 17 includes, for example, an input device such as a keyboard and a mouse.

The output unit 16 is a display device (for example, display, printer) that displays the drawing data created by the drawing processor 15 as a drawing.

The display condition data storage 13 stores display condition data. The display condition data is data (for example, later-described area, work object facility, work content type, work company, (designated) period) designating a display range and a display method of a work object in the drawing created by the drawing processor 15. The work object included in a display range in the display condition data is displayed in the drawing by the drawing processor 15. Besides, the display method of a work object is, for example, a color or transmittance when the work object is displayed in the drawing.

The display condition data is designated, for example, in a display condition setting screen as illustrated in FIG. 3. In the display condition setting screen, the area, the work object facility, the work content type, and the work company can be selected, and the selected range can be set as a display object or a non-display object.

As the area, an arbitrary range from each area, construction section, or map, besides all area, can be designated. As the work object facility, for example, each device, piping, or cable tray, besides all facility, can be designated for each facility of the work object. As the work content type, for example, carry-in, welding, or inspection, besides all work contents, can be designated for each facility being the work object. As the work company, a company performing a work such as Company A or Company B, besides all work companies, can be designated.

In the display condition setting screen, a period including future can be set as a designated period. Time before the designated period is called a first period, time during the designated period is called a second period, and time after the designated period is called a third period. The first period may be a period before the second period, or may include whole time before the second period. Similarly, the third period may be a period after the second period, or may include whole time after the second period. Further, the length of each of the first period, the second period, and the third period may be the same or different. The length of each of the first period, the second period, and the third period may be in a unit of day, a unit of hour, or a unit of minute.

For example, when the designated period is this week, the second period is this one week. In this case, when the first period is a fixed period before the second period, the first period is, for example, the last one week. When the first period includes whole time before the second period, the first period is the last week and therebefore. Similarly, when the third period is a fixed period after the second period, the third period is, for example, the next one week. When the third period includes whole time after the second period, the third period is the next week and thereafter.

Describing more specifically, when it is May 2 at present, the second period can be set to one week from May 1 to May 7 in the same year. The third period can be set either to May 8 to May 10 in the same year or to May 8 and therebefore in the same year. Further, the first period in the same year can be set either to April 25 to April 30 or to April 30 and therebefore in the same year.

Here, an object for which work has been completed in the first period, namely, an object for which work has been completed before the designated period is called a “first work object”. A work object planned in the second period, namely, an object for which work is planned to be performed within the designated period is called a “second work object”. A work object planned in the third period, namely, an object for which work is planned to be performed after the designated period is called a “third work object”.

Further, in the display condition setting screen, a first work color, a second work color, and a third work color can be designated to correspond to the first work object, the second work object, and the third work object, respectively. In the drawing created by the drawing processor 15, the work objects corresponding to the first work object, the second work object, and the third work object are displayed in the first work color, the second work color, and the third work color, respectively.

For example, in the display condition setting screen in FIG. 3, the first period, the second period, and the third period are the last week, this week, and the next week, respectively. The first work color, the second work color, and the third work color are blue, red, and pink, respectively.

Note that to the display condition data storage 13, an input unit 18 is connected, so that the display condition data can be changed from the input unit 18. The input unit 18 is, for example, an input device such as a keyboard or a mouse.

The drawing processor 15 is an arithmetic unit and creates a drawing of a solid or a plane, for example, according to a CAD drawing creation program. The drawing processor 15 accesses the display condition data in the display condition data storage 13 and the operation process data in the operation process data storage 12, reads from the design data storage the design data on work objects corresponding to one of the first period, the second period, and the third period and corresponding to the display range, and creates drawing data. The drawing processor 15 further creates, based on the first work color, the second work color, and the third work color in the display condition data in the display condition data storage 13, drawing data in which the first work object, the second work object, and the third work object are displayed colored the aforementioned first work color, the aforementioned second work color, and the aforementioned third work color, respectively.

The interference confirmation unit 14 has, as has been described, the storage part and the determination part. The storage part includes a storage which stores interference condition data. The interference condition data represents (spacial) conditions where work processes interfere with each other between the work objects such as predetermined and vertically overlapping works, spaces necessary for respective works. The arithmetic unit (determination part) of the interference confirmation unit 14 includes a processor which accesses the interference condition data and the drawing data, and determines whether or not there is work interference between the work objects colored the second work color. In the case where there are work-interfering work objects, the drawing data is corrected to be outputted such that the work objects are colored in specific display (for example, yellow) showing process interference, on the drawing data, as work objects requiring adjustment.

Although the presence or absence of work interference at the second work object is confirmed here, the presence or absence of work interference at a work object appropriately selected from the first to third work objects may be confirmed. Further, the presence or absence of work interference of not the whole selected work object but a part of the work object may be confirmed.

Note that the color of a process interfering portion is not particularly changed, but the period, place, object facility information and the like of the interfering portion may be outputted in a list. Further, the color of the process interfering portion is not particularly changed, but a specific mark or design indicating process interference may be displayed at the process interfering portion.

The drawing data is created by the drawing processor 15, subjected to check for work interference by the interference confirmation unit 14, and displayed (outputted) as a drawing at the output unit 16.

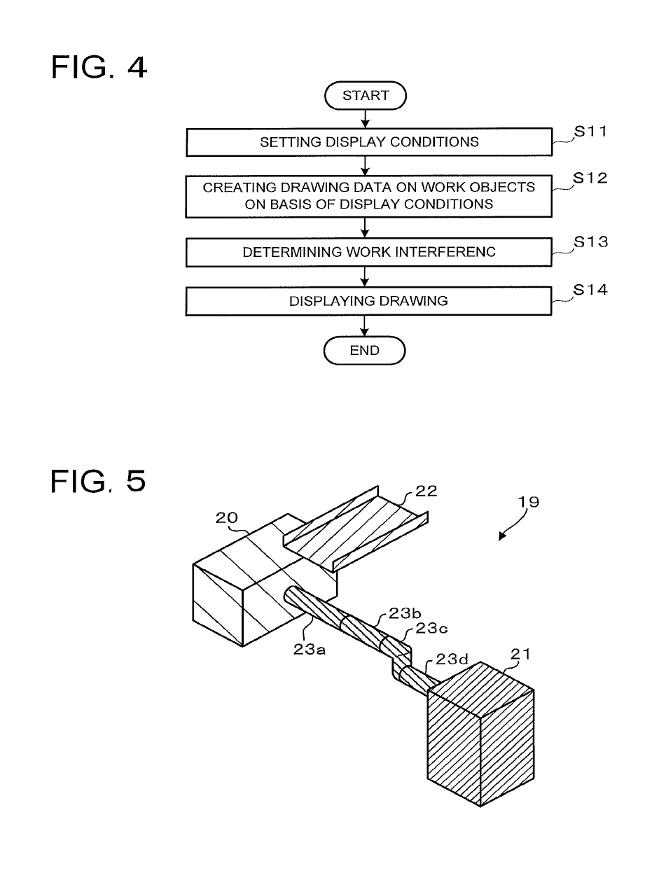

Hereinafter, the operation of the work plan range visualization apparatus 1 in this embodiment will be described referring to FIG. 4. FIG. 4 is a flowchart illustrating the operation of the work plan range visualization apparatus 1. The operation of the work plan range visualization apparatus 1 has Step S11 of setting display conditions, Step S12 of creating drawing data on work objects on the basis of the display conditions, Step S13 of determining work interference, and Step S14 of displaying a drawing.

At Step S11, the display condition data is set from the input unit 18 connected to the display condition data storage 13. More specifically, conditions in the display condition setting screen in FIG. 3 are set. For example, the range of the drawing data is selected from “area”, “work object facility”, “work content type”, and “work company”. Further, the first period, the second period, and the third period are set in “period”, and the first work color, the second work color, and the third work color are set in “color”.

At Step S12, the drawing processor 15 accesses the display condition data in the display condition data storage 13 and the operation process data in the operation process data storage 12, reads from the design data storage the design data on work objects corresponding to one of the first period, the second period, and the third period and corresponding to the display range, and creates drawing data. The drawing processor 15 further creates, based on the first work color, the second work color, and the third work color in the display condition data in the display condition data storage 13, drawing data in which the first work object, the second work object, and the third work object are displayed colored the first work color, the second work color, and the third work color, respectively.

At Step S13, the interference confirmation unit 14 accesses the interference condition data and the drawing data, and determines whether or not there is work interference between the work objects colored the second work color. In the case where there are work-interfering work objects, the drawing data is corrected to be outputted such that the work objects are colored specific color (for example, yellow) showing process interference, on the drawing data, as work objects requiring adjustment in work period and work object.

At Step S14, the output unit 16 displays the drawing data created by the drawing processor 15 and subjected to check for interference by the interference confirmation unit 14 as a drawing.

FIG. 5 is an example of the drawing outputted at Step S14. A work object 19 displayed in the drawing is set as a work object in the display condition data in the display condition data storage 13. For example, regarding FIG. 5, the first period is set as the last week and therebefore, the second period is set as this week, and the third period is set as the next week and thereafter in the display condition data. Further, the first work color, the second work color, and the third work color are set as blue, red, and pink, respectively. More specifically, in the display condition data, a portion for which work has been completed in the last week and therebefore is indicated with blue, a portion of work objects in this week is indicated with red, and a portion for which worked is planned to be performed in the next week and thereafter is indicated with pink in FIG. 5. In FIG. 5, a work object 20 is blue, a work object 21 is red, and a work object 22 is pink. Further, work objects 23a, 23b, 23c, 23d are portions corresponding to the second work objects, and an object having process interference determined by a process interference check unit 33 and indicated with yellow. The work objects 23a to 23d are spatially continuously arranged. Therefore, work processes interfere with each other between the work objects 23a and 23b, between the work objects 23b and 23c, and between the work objects 23c and 23d.

Note that when the first period is a certain period, a plurality of periods may be set before the first period, and work objects corresponding to the periods respectively may be colored colors different from those of the first to third periods. Similarly, when the third period is a certain period, a plurality of periods may be set after the third period, and work objects corresponding to the periods respectively may be colored colors different from those of the first to third periods.

Besides, the first work color, the second work color, and the third work color may be the same color different in transmittance, or the first work color, the second work color, and the third work color may be set to the same color as the color of the background of the drawing. Displaying the drawing every time the first work color, the second work color, and the third work color are sequentially set from the background color to a color different from that of the background makes it possible to indicate the work objects in a time-series manner.

Besides, a portion being a non-display object in the display condition data may be displayed in a color or transmittance different from that of the display object in the drawing. For example, a portion other than the display object may be displayed in gray.

The work plan range visualization apparatus 1 in this embodiment can display, in a color-coding manner, a processed object, an object which is an unprocessed object and for which work is planned to be performed within a certain period, and an object which is an unprocessed object and for which work is planned to be performed after a certain period. In other words, it is possible to create a drawing with which a work plan over time can be intuitively grasped so as to easily confirm an object for which work has been completed and a planned work range in a period such as this week or the next week. Therefore, it is possible to confirm the progress status of construction and the process interference in an execution plan to be performed at a glance, thereby reducing the process adjustment work time.

In addition, the following effects can be achieved by this embodiment.

The man-hour for preparing a work adjustment material for a process meeting can be reduced.

The arrangement efficiency and the sensitivity to risk can be improved by visualization of the work range.

The waiting man-hour due to work interference can be reduced.

The delay in progress of construction can be confirmed at an early stage by visualization of residual work.

The progress status of construction can be visually shared between the headquarters and the construction site.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A work range visualization device comprising:
a design data storage which stores design data on work objects;
an operation process data storage which stores operation process data based on the design data;
a display condition data storage which stores a designated period including present and future; and
a drawing processor which extracts data for a first, a second, and a third work object from the design data and the operation process data according to the designated period, and creates a drawing in which each of the first, the second and the third work object is distinguishable, wherein the first work object is an object completed before the designated period, the second work object is an object planned to be operated within the designated period and the third work object is an object planned to be operated after the designated period.

2. The work range visualization device according to claim 1, wherein:
the display condition data storage stores a first, a second, and a third work color corresponding to the first, the second, and the third work object, respectively; and
the drawing processor creates a drawing in which the first, the second and the third work object is drawn with the first, a second, and a third work color, respectively.

3. The work range visualization device according to claim 1, further comprising:
a confirmation unit which includes a processor and storage, stores interference condition data and confirms presence or absence of work process interference between work objects at at least of one of the first, second, and third work objects, wherein
the drawing processor creates the drawing in which the work object confirmed to have the interference is distinguishable from other work objects.

4. The work range visualization device according to claim 1, wherein the design data is 3D CAD data.

5. The work range visualization device according to claim 1, further comprising a change input unit which includes keyboard and changes the operation process data.

6. A work range visualization method comprising:
a drawing processor extracting design data stored in a design data storage and operation process data from an operation process data storage according to a designated period stored in a display condition data storage for a first, a second and a third work object, which the first work object is an object completed before the designated period, the second work object is an object planned to be operated within the designated period and the third work object is an object planned to be operated after the designated period;
the drawing processor creating a drawing in which each of the first, the second and the third work object is distinguishable.

7. The work range visualization method according to claim 6, wherein:
the drawing processor creating a drawing in which the first, the second and the third work object is drawn with the first, a second, and a third work color, respectively, which the first, second, and third work color are stored in the display condition data storage.

8. The work range visualization method according to claim 6, further comprising:
a confirmation unit confirming presence or absence of work process interference between work objects at at least of one of the first, the second, and the third work object; and
the drawing processor creating the drawing in which the work object confirmed to have the interference is distinguishable from other work objects, wherein the confirmation unit includes a processor and storage.

9. The work range visualization method according to claim 6, wherein the design data is 3D CAD data.
